(19) United States
(12) Patent Application Publication
(10) Pub. No.: US 2026/0159442 A1
(43) Pub. Date: Jun. 11, 2026

(54) HARD COATING FILM, AND WINDOW AND IMAGE DISPLAY DEVICE HAVING SAME APPLIED THERETO

(71) Applicant: DONGWOO FINE-CHEM CO., LTD., Iksan-si (KR)

(72) Inventors: Seung-Hee KIM, Iksan-si (KR); Geo-San LIM, Iksan-si (KR); Jong-Han CHOI, Iksan-si (KR)

(73) Assignee: DONGWOO FINE-CHEM CO., LTD., Iksan-si (KR)

(21) Appl. No.: 18/878,798

(22) PCT Filed: May 30, 2023
(86) PCT No.: PCT/KR2023/007381

§ 371 Date: Dec. 24, 2024

(30) Foreign Application Priority Data
Jun. 30, 2022 (KR) 10-2022-0080540

(51) Int. Cl. C03C 17/42; C09D 4/00; C09D 7/40; C09D 7/65; C09D 133/14; C09D 135/02; H05K 5/03

(52) U.S. Cl. CPC C03C 17/42; C09D 4/00; C09D 7/65; C09D 7/67; C09D 133/14; C09D 135/02; H05K 5/03; C03C 2217/445; C03C 2217/78

(57) ABSTRACT

The present disclosure relates to a hard coating film which has a pencil hardness of 3H or higher and excellent scratch resistance, antifouling properties, wear resistance, chemical resistance, pressing resistance, anti-scattering properties, adhesion, and flexural properties by including: a first hard coating layer which is formed on a display glass, contains a silane or siloxane compound, and has a Vickers hardness of 20 kgf/mm² or less; and a second hard coating layer which is formed on the first hard coating layer, contains a fluorine-based UV curable functional group-containing compound, and has a thickness of 3 to 15 μm, and a window and an image display device applying the same.

### TECHNICAL FIELD

The present disclosure relates to a hard coating film and a window and an image display device applying the same.

### BACKGROUND ART

Recently, thinning and flexibility of image display devices such as liquid crystal display (LCD) devices or organic light emitting display (OLED) devices are continuously being developed. The image display devices are widely applied to various smart devices characterized by portability, such as smart phones, tablet PCs, and various wearable devices. Such flexible displays require a glass substrate layer having properties such as high transparency, hardness, bending characteristics, etc.

Meanwhile, flexible displays may frequently have problems with cover glass breaking when folded frequently or when impact exceeding the limit is applied. In this case, a large amount of small pieces of glass may be scattered, which may cause quality degradation problems such as foreign substances on the surface of the display and the device, and may lead to safety accidents at the same time. In order to prevent this and ensure stability against glass fragments in the event of breakage, a scattering prevention film, etc. may be included in the window layer.

Korean Patent Registration Gazette No. 10-1408511 provides a transparent substrate which significantly prevents the progression of cracks and breakage of thin glass and has excellent flexural properties and flexibility by reinforcing thin glass by providing a resin layer having a specific shrinkage stress on one or both sides of thin glass.

However, there is a disadvantage in that the substrate manufacturing process becomes complicated since an adhesive layer is disposed to be interposed on the surface of one or both surfaces of thin glass to form the resin layer.

Accordingly, there is a need to develop a hard coating film that forms a substrate layer for preventing scattering directly on glass, thereby simplifying the process, is excellent in adhesion, and has durability suitable for implementing flexible characteristics.

### DISCLOSURE

### Technical Problem

In order to solve the above-described problems, it is an object of the present disclosure to provide a hard coating film with excellent quality that prevents scattering of fragments during breakage.

Specifically, it is one object of the present disclosure to provide a window and an image display device that are excellent in scratch resistance, antifouling properties, wear resistance, chemical resistance, pressing resistance, anti-flying properties, adhesion, and flexural properties while having high hardness when the hard coating film is applied.

However, the problems to be solved by the present disclosure are not limited to the problems mentioned above, and other problems not mentioned will be clearly understood by those skilled in the art from the description below.

### Technical Solution

In order to achieve the above technical problems, the present disclosure provides a hard coating film including: a first hard coating layer which is formed on a display glass, contains a silane or siloxane compound, and has a Vickers hardness of 20 kgf/mm² or less; and a second hard coating layer which is formed on the first hard coating layer, contains a fluorine-based UV curable functional group-containing compound, and has a thickness of 3 to 15 μm.

The present disclosure may be that the display glass is an ultrathin glass (UTG).

The present disclosure may be that the display glass, the first hard coating layer, and the second hard coating layer are formed by directly contacting each other without including a separate layer.

The present disclosure may be that the fluorine-based UV curable functional group-containing compound has 1 to 6 UV-curable functional groups.

The present disclosure may be that any one hard coating layer of the first hard coating layer and the second hard coating layer is prepared from a composition comprising one or more selected from the group consisting of a photopolymerizable compound, an initiator, and a solvent.

The present disclosure may be that the photopolymerizable compound further includes an inorganic nano filler.

The present disclosure may be that any one hard coating layer of the first hard coating layer and the second hard coating layer further contains an additive.

The present disclosure may be that the additive includes one or more selected from the group consisting of a leveling agent, an ultraviolet stabilizer, and a heat stabilizer.

The present disclosure may be that it is applied to a flexible display.

Furthermore, the present disclosure relates to a window including: a display glass; and the hard coating film formed on the display glass.

Furthermore, the present disclosure relates to an image display device including the window.

### Advantageous Effects

The hard coating film according to the present disclosure and the window and image display device applying the same may have improved device reliability when applied to a flexible display by having a pencil hardness of 3H or higher and excellent scratch resistance, antifouling properties, wear resistance, chemical resistance, pressing resistance, anti-scattering properties, adhesion, and flexural properties.

In addition, the hard coating film according to the present disclosure is formed by direct contact without including a separate substrate between glass and the hard coating layer, so that a process for bonding each substrate layer can be omitted, and thus the manufacturing process may be simplified compared to the conventional one.

### DESCRIPTION OF DRAWINGS

FIG. 1 illustrates a laminated structure of a display glass on which a hard coating film according to one embodiment of the present disclosure is laminated.

The respective reference numerals on the drawings represent the following:
100: Laminate
110: Display glass
120a: First hard coating layer
120b: Second hard coating layer

### BEST MODE FOR CARRYING OUT THE INVENTION

The present disclosure relates to a hard coating film which is suitable for use in a flexible display by including: a first hard coating layer which is formed on a display glass, contains a silane or siloxane compound, and has a Vickers hardness of 20 kgf/mm² or less; and a second hard coating layer which is formed on the first hard coating layer, contains a fluorine-based UV curable functional group-containing compound, and has a thickness of 3 to 15 μm, and a window and an image display device using the same.

Hereinafter, preferred embodiments of the present disclosure will be described in detail. However, these embodiments are merely presented exemplarily to more specifically explain the present disclosure, and it will be obvious to those skilled in the art that the scope of the present disclosure is not limited by these embodiments.

The terms used in the present specification are for the purpose of describing embodiments and are not intended to limit the present disclosure. In the present specification, singular forms also include plural forms unless specifically stated otherwise in the phrases. For example, the “hard coating layer” used in the present specification may mean at least one hard coating layer out of the first hard coating layer and the second hard coating layer.

The terms “comprises” and/or “comprising” used in the present specification are used to mean that they do not exclude the presence or addition of one or more other components, steps, operations, and/or elements other than the mentioned components, steps, operations, and/or elements. The same reference numerals refer to the same components throughout the specification.

“Substantially” used in the present specification may be interpreted to include not only physically completely identical or coincide, but also within a range of error in the measurement or manufacturing process, for example, it may be interpreted to mean a range of error of 0.1% or less.

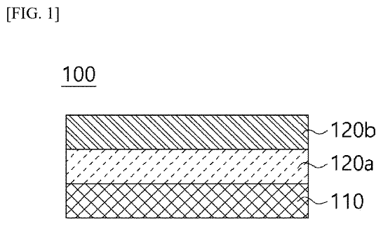

FIG. 1 illustrates a laminated structure of a display glass on which a hard coating film according to one embodiment of the present disclosure is laminated, and the laminate 100 of the present disclosure, as shown in FIG. 1, may be a structure of: a display glass 110; a first hard coating layer 120a formed on the display glass 110; and a second hard coating layer 120b formed on the first hard coating layer, i.e., on the outermost portion.

The hard coating film of the present disclosure may have hardness and flexibility at the same time in order to be applied to a flexible display window.

### <Display Glass (110)>

The display glass is for supporting a hard coating layer 120 and other substrates or panels, which will be described later, by substituting an existing glass substrate, and may be composed of either a thin glass or a curved glass for the display of an electronic device. The thin glass may include a flat glass and a flexible glass.

According to one embodiment of the present disclosure, the display glass 110 may apply an ultrathin glass (UTG). The ultrathin glass (UTG), as a component made of an ultrathin tempered glass material used for a display cover window, has the characteristic of being flexibly foldable by having high transparency and a thin thickness of about 10 to 100 μm.

In the present disclosure, the term “transparent” means that the visible light transmittance is 70% or more or 80% or more, but is not limited thereto.

The display glass 110 may include an additional substrate layer, such as a hard coating layer 120 or the like to be described later, to secure durability. Generally, an adhesive layer or a pressure-sensitive adhesive layer is included to form or bond the substrate layer, but the hard coating film according to the present disclosure is characterized by being formed by direct contact without including a separate substrate layer for bonding the hard coating layer, so that the manufacturing process may be simplified compared to a conventional laminate.

### <Hard Coating Film>

The hard coating film of the present disclosure includes a hard coating layer, and preferably includes a first hard coating layer and a second hard coating layer. More specifically, the hard coating film of the present disclosure may include a first hard coating layer which is formed on the display glass, contains a silane or siloxane compound, and has a Vickers hardness of 20 kgf/mm² or less; and a second hard coating layer which is formed on the first hard coating layer, contains a fluorine-based UV-curable functional group-containing compound, and has a thickness of 3 to 15 μm.

### Hard Coating Layer (120)

The hard coating layer of the present disclosure may include a first hard coating layer 120a and a second hard coating layer 120b as illustrated in FIG. 1.

According to one embodiment of the present disclosure, the first hard coating layer 120a is characterized by including a silane or siloxane compound and having a Vickers hardness of 20 kgf/mm² or less, and as the Vickers hardness satisfies the above range, it serves to prevent flying of fragments when the window is broken. In addition, the second hard coating layer 120b is exposed to the surface to provide antifouling properties and a function of protecting the film. The second hard coating layer 120b is characterized by containing a fluorine-based UV-curable functional group-containing compound and having a thickness of 3 to 15 μm.

Referring to FIG. 1, the first hard coating layer 120a may be formed on the display glass 110, and the second hard coating layer 120b may be formed on the first hard coating layer 120a, that is, on the outermost portion of the hard coating film. The first hard coating layer 120a secures adhesion between substrates and provides impact resistance even without a layer such as a separate substrate layer such as a pressure-sensitive adhesive layer.

According to one embodiment of the present disclosure, the display glass 110 may apply an ultrathin glass (UTG) as described above, and the display glass 110, the first hard coating layer 120a, and the second hard coating layer 120b may be formed by directly contacting each other without including a separate layer.

In addition, the first hard coating layer 120a and the second hard coating layer 120b may be each independently prepared from a hard coating composition comprising one or more selected from the group consisting of a photopolymerizable compound, a solvent, and an initiator, and the composition may further comprise one or more selected from the group consisting of a leveling agent, an ultraviolet stabilizer, and a heat stabilizer as an additive, if necessary. For example, the first hard coating layer may be prepared from a hard coating composition comprising a silane or siloxane compound, a photopolymerizable compound, an initiator, and a solvent.

In addition, the second hard coating layer may be prepared from a hard coating composition comprising a fluorine-based UV-curable functional group-containing compound, a photopolymerizable compound, an initiator, and a solvent.

### Silane or Siloxane Compound

The siloxane compound included in the first hard coating layer 120a of the present disclosure includes a compound having a Si—O—Si bond. In the present disclosure, the bonding strength of Si—O of the siloxane compound is stronger than that of the C—C bond, so that it may impart characteristics that are not only excellent in impact resistance, but also excellent in adhesion to adjacent substrates. In addition, the bonding length of the Si—O is longer than that of the C—C, and the bonding angle of Si—O—Si is 143°, which is larger than the bonding angle of the C—C—C bond of 110°, so that it has excellent flexibility against deformation. Therefore, the silane or siloxane compound of the present disclosure has excellent elastic recovery rate compared to carbon materials. The siloxane compound may be in the form of —(R₂SiO)— in which two organic groups are bonded to a silicon element, or in the form of —(RSiO_{1.5})— in which one organic group is bonded thereto. An example of the —(R₂SiO)— form may include polydimethylsiloxane (PDMS). Examples of the —(RSiO_{1.5})— form may include cage-type silsesquioxane, partially cage-type silsesquioxane, ladder-type silsesquioxane, random-type silsesquioxane, etc. The organic group may have a photocurable (meth)acrylic functional group or epoxy functional group.

The silane compound includes a compound having an X—Si—(OR)₃ bond, but is not limited thereto. For example, examples of the X—Si—(OR)₃ type may include a silane coupling agent, etc. X of the silane compound may have a photocurable (meth)acrylic functional group or an epoxy functional group as a reactive group that chemically bonds with an organic material. R of the silane or siloxane compound refers to any organic group, and includes organic groups of known silane or siloxane compounds without limitation.

According to one embodiment of the present disclosure, the silane or siloxane compound may be included in an amount of 1 to 10 parts by weight, preferably 3 to 10 parts by weight, based on 100 parts by weight of the hard coating composition. The hard coating layer formed of the hard coating composition by comprising the silane or siloxane compound in the above range has good adhesion between substrates, may provide flexibility to the film substrate layer, and may prevent broken fragments from flying when broken by frequent folding or external impact.

### Fluorine-Based UV-Curable Functional Group-Containing Compound

The fluorine-based UV-curable functional group-containing compound included in the second hard coating layer 120b of the present disclosure must contain fluorine as a component that provides antifouling properties and wear resistance, and is not particularly limited as long as it has a UV-curable functional group along therewith.

Specifically, acrylates, methacrylates, vinyls, etc. containing perfluoro groups may be used. At this time, it is preferable that the fluorine-based UV-curable functional group-containing compound has 1 to 6 UV-curable functional groups, but the scope of the present disclosure is not limited thereto, and any material containing a fluorine group while having a UV-curable functional group can be applied.

It is preferable to be included in an amount of 0.01 to 30 parts by weight based on 100 parts by weight of the total hard coating composition. If it is included in an amount of less than 0.01 parts by weight, it is difficult to sufficiently secure wear resistance and antifouling properties, and if it is included in an amount exceeding 30 parts by weight, the film hardness and wear resistance may be rather reduced.

### Photopolymerizable Compound

The photopolymerizable compound used in the formation of the hard coating layer of the present disclosure contains a photopolymerizable functional group, and may be a photopolymerizable monomer, a photopolymerizable oligomer, etc., and may be, for example, a photoradical polymerizable compound.

A commonly used photocurable functional group of the photopolymerizable monomer may include, for example, a monomer used in the relevant technical field having an unsaturated group such as a (meth)acryloyl group, a vinyl group, a styryl group, an allyl group, or the like in the molecule without limitation, and more specifically, the photopolymerizable monomer may include, for example, monofunctional and/or polyfunctional (meth)acrylates. These may be used alone or in mixtures of two or more.

In the present disclosure, “(meth)acryl-” refers to “methacryl-”, “acryl-”, or both.

Specific examples of (meth)acrylate monomers may include (meth)acrylic acid esters, such as trimethylolpropane tri(meth)acrylate, pentaerythritol tri(meth)acrylate, glycerol tri(meth)acrylate, tris(2-hydroxyethyl)isocyanurate tri(meth)acrylate, ethylene glycol di(meth)acrylate, propylene glycol (meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, Bis(2-hydroxyethyl)isocyanurate di(meth)acrylate, and poly(meth)acrylates prepared by adding ethylene oxide or propylene oxide to the (meth)acrylic acid esters; oligoester (meth)acrylates having 1 to 3 (meth)acryloyl groups in the molecule, oligoether (meth)acrylic acid esters, oligourethane (meth)acrylic acid esters, and oligoepoxy (meth)acrylic acid esters; hydroxyethyl (meth)acrylate, hydroxypropyl (meth)acrylate, hydroxybutyl (meth)acrylate, and products prepared by adding ethylene oxide or propylene oxide to the (meth)acrylic acid esters; and mono(meth)acrylic acid esters, for example, monomers having a trifunctional or less (meth)acryloyl group such as iso-octyl (meth)acrylate, iso-decyl (meth)acrylate, stearyl (meth)acrylate, tetrahydrofurfuryl (meth)acrylate, and phenoxyethyl (meth)acrylate, and dipentaerythritol hexa(meth)acrylate, dipentaerythritol hydroxypenta(meth)acrylate, pentaerythritol tetra(meth)acrylate, ditrimethylolpropane tetra(meth)acrylate, etc. These may be used alone or in mixtures of two or more.

The photopolymerizable oligomer may include, for example, one or more selected from the group consisting of an epoxy (meth)acrylate, a urethane (meth)acrylate, and a polyester (meth)acrylate, and specifically, may include a mixture of a urethane (meth)acrylate and a polyester (meth)acrylate, or a mixture of two types of polyester (meth)acrylates. It is preferable to include urethane (meth)acrylate oligomers in order to improve the scratch resistance and hardness of the cured product and increase the elastic modulus of the hard coating layer.

The urethane (meth)acrylate may be prepared by reacting a polyfunctional (meth)acrylate having a hydroxyl group in the molecule with a compound having an isocyanate group in the presence of a catalyst according to a method known in the art.

Specific examples of the polyfunctional (meth)acrylate having a hydroxy group in the molecule may include one or more selected from the group consisting of 2-hydroxyethyl (meth)acrylate, 2-hydroxyisopropyl (meth)acrylate, 4-hydroxybutyl (meth)acrylate, caprolactone ring-opening hydroxyacrylate, a pentaerythritol tri/tetra(meth)acrylate mixture, and a dipentaerythritol penta/hexa(meth)acrylate mixture.

In addition, specific examples of the compound having an isocyanate group may include one or more selected from the group consisting of 1,4-diisocyanatobutane, 1,6-diisocyanatohexane, 1,8-diisocyanatooctane, 1,12-diisocyanatododecane, 1,5-diisocyanato-2-methylpentane, trimethyl-1,6-diisocyanatohexane, 1,3-bis(isocyanatomethyl)cyclohexane, trans-1,4-cyclohexenediisocyanate, 4,4′-methylenebis(cyclohexylisocyanate), isophoronediisocyanate, toluene-2,4-diisocyanate, toluene-2,6-diisocyanate, xylene-1,4-diisocyanate, tetramethylxylene-1,3-diisocyanate, 1-chloromethyl-2,4-diisocyanate, 4,4′-methylenebis(2,6-dimethylphenylisocyanate), 4,4′-oxybis(phenylisocyanate), a trifunctional isocyanate derived from hexamethylene diisocyanate, and trimethanepropanol adduct toluene diisocyanate.

More specifically, the urethane (meth)acrylate oligomers may be compounds each containing two or more substituents and (meth)acroyl groups represented by Chemical Formula 1 below in the molecule.

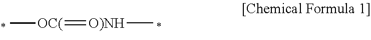

The urethane (meth)acrylate oligomers may be produced by reacting 1 mol of a diisocyanate represented by Chemical Formula 2 below with 2 mol of an active hydrogen-containing polymerizable unsaturated compound.

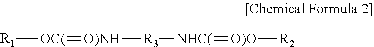

In the formula, R₁ and R₂ are each independently a substituent including a (meth)acryloyl group derived from an active hydrogen-containing polymerizable unsaturated compound, and R₃ is a divalent substituent derived from diisocyanate.

Specific examples of urethane (meth)acrylate oligomers may include products of the reaction of 2-hydroxyethyl (meth)acrylate and 2,4-tolylene diisocyanate, the reaction of 2-hydroxyethyl (meth)acrylate and isophorone diisocyanate, the reaction of 2-hydroxybutyl (meth)acrylate and 2,4-tolylene diisocyanate, the reaction of 2-hydroxybutyl (meth)acrylate and isophorone diisocyanate, the reaction of pentaerythritol tri(meth)acrylate and 2,4-toluene diisocyanate, the reaction of pentaerythritol tri(meth)acrylate and isophorone diisocyanate, the reaction of pentaerythritol tri(meth)acrylate and dicyclohexyl methane diisocyanate, the reaction of dipentaerythritol penta(meth)acrylate and isophorone diisocyanate, and the reaction of dipentaerythritol penta(meth)acrylate and dicyclohexyl methane diisocyanate.

The polyester (meth)acrylate may be prepared by reacting a polyester polyol with acrylic acid according to a method known in the art.

The polyester (meth)acrylate may include, for example, one or more selected from the group consisting of polyester acrylate, polyester diacrylate, polyester tetraacrylate, polyester hexaacrylate, polyester pentaerythritol triacrylate, polyester pentaerythritol tetraacrylate, and polyester pentaerythritol hexaacrylate, but is not limited thereto.

The photopolymerizable monomer and the photopolymerizable oligomer may be used alone or in mixtures. When the photopolymerizable monomer and the photopolymerizable oligomer are used in mixtures, the workability and compatibility of the hard coating composition can be increased.

The content ratio of the photopolymerizable monomer and the photopolymerizable oligomer is not particularly limited and may be appropriately selected in consideration of the storage elastic modulus, shrinkage force, and workability of the hard coating layer, and they may be included, for example, at content ratio of the polymerizable oligomer to the polymerizable monomer of (1:10) to (10:1). When the content ratio of the polymerizable oligomer to the polymerizable monomer is out of the above range, the storage elastic modulus of the hard coating layer may decrease or the shrinkage force may increase, resulting in a decrease in hardness and flexibility, which may cause curling.

The content of the photopolymerizable compound is not particularly limited, but it may be included in an amount of, for example, 1 to 80 parts by weight, preferably 5 to 50 parts by weight, based on 100 parts by weight of the total hard coating composition. When the polymerizable compound is included in an amount of less than 1 part by weight, the elastic modulus of the hard coating layer decreases, so that cracks may easily occur in the hard coating layer when bent, and when it is included in an amount exceeding 80 parts by weight, the viscosity increases, so that the applicability deteriorates, and the surface leveling is insufficient, which may cause problems in the appearance characteristics.

The photopolymerizable compound may be used together with an inorganic nanofiller to improve hardness and scratch resistance. The inorganic nanofiller may include nanofillers of generally less than 100 nm, preferably 10 to 100 nm, and more preferably 10 to 50 nm. Representative inorganic nanofillers may include, for example, silica, aluminum oxide particles, titanium oxide particles, zinc oxide particles, etc., and preferably include silica. Silica may one which has a photocurable group capable of participating in a photoreaction on the surface, or one which does not have it.

The inorganic nano filler can be added by appropriately adjusting the content within a range that does not hinder the effects of the present disclosure.

### Solvent

The solvent is one capable of dissolving or dispersing the composition mentioned above, and can be used without limitation as long as it is known as a solvent for a composition for the formation of a coating layer in this technical field.

Available solvents may preferably include alcohol-based solvents (methanol, ethanol, isopropanol, butanol, methyl cellosolve, ethyl cellosolve, etc.), ketone-based solvents (methyl ethyl ketone, methyl butyl ketone, methyl isobutyl ketone, diethyl ketone, dipropyl ketone, cyclohexanone, etc.), acetate-based solvents (ethyl acetate, propyl acetate, normal butyl acetate, tert-butyl acetate, methyl cellosolve acetate, ethyl cellosolve acetate, propylene glycol monomethyl ether acetate, propylene glycol monoethyl ether acetate, propylene glycol monopropyl ether acetate, methoxybutyl acetate, methoxypentyl acetate, etc.), hexane-based solvents (hexane, heptane, octane, etc.), benzene-based solvents (benzene, toluene, xylene, etc.), ether-based solvents (diethylene glycol dimethyl ether, diethylene glycol diethyl ether, diethylene glycol dipropyl ether, diethylene glycol dibutyl ether, propylene glycol monomethyl ether, etc.), etc. The solvents exemplified above can be used alone or in combinations of two or more.

Such a solvent is used in an amount of 10 to 95 parts by weight based on 100 parts by weight of the total hard coating composition. If the content of the solvent is less than the above content, the viscosity is high, which not only reduces workability, but also makes it difficult to sufficiently promote swelling of the base film. On the contrary, since it takes a lot of time in the drying process and causes problems of reduced economic efficiency if the content exceeds the above range, it is appropriately used within the above range.

### Initiator

The initiator can be used without limitation as long as it is used in the relevant technical field. It may include, for example, one or more selected from the group consisting of hydroxyketone, aminoketone, hydrogen abstraction-type photoinitiator, and combinations thereof.

Specifically, the photoinitiator may include one or more selected from the group consisting of 2-methyl-1-[4-(methylthio)phenyl]2-morpholinepropanone-1, diphenyl ketone, benzyl dimethyl ketal, 2-hydroxy-2-methyl-1-phenyl-1-one, 4-hydroxycyclophenyl ketone, 2,2-dimethoxy-2-phenyl-acetophenone, anthraquinone, fluorene, triphenylamine, carbazole, 3-methylacetophenone, 4-xenoloacetophenone, 4,4-dimethoxyacetophenone, 4,4-diaminobenzophenone, 1-hydroxycyclohexyl phenyl ketone, benzophenone, diphenyl(2,4,6-trimethylbenzoyl)phosphine oxide, and combinations thereof.

Such photoinitiators are used in a range of 0.1 to 10 parts by weight, preferably 1 to 5 parts by weight, based on 100 parts by weight of the total hard coating composition. If the content is less than the above range, the curing speed of the composition is slow and under-curing occurs, resulting in poor mechanical properties, and on the contrary, if the content exceeds the above range, cracks may occur in the coating film due to over-curing.

### Additives

In addition, the hard coating composition used in the formation of the hard coating layer according to the present disclosure may further comprise additives such as a leveling agent, an ultraviolet stabilizer, and/or a heat stabilizer.

The leveling agent is a component that provides the smoothness and coating properties of the coating film. The leveling agent can be applied as a leveling agent commonly used in the art, and examples thereof may include a silicone-based leveling agent, a fluorine-based leveling agent, and an acrylic polymer-based leveling agent. These may be used alone or in combination of two or more, but are not necessarily limited thereto.

The leveling agent may be included in an amount of 0.1 to 1 part by weight based on 100 parts by weight of the hard coating composition, but is not limited thereto.

The ultraviolet stabilizer is a component that blocks or absorbs ultraviolet rays, thereby preventing decomposition, discoloration, and crumbling of the cured hard coating layer due to exposure to ultraviolet rays. The ultraviolet stabilizer may include absorbers, quenchers, and hindered amine light stabilizers (HALS) divided depending on their mechanism of action; or phenyl salicylates (absorbent), benzophenone (absorbent), benzotriazole (absorbent), nickel derivatives (quenchers), radical scavengers divided depending on the chemical structure. These may be used alone or in combination of two or more, and the types of the UV stabilizers are not particularly limited as long as they do not significantly change the initial color of the hard coating layer.

The heat stabilizer may include, for example, as commercially applicable products, a commercially applicable products, a polyphenol-based primary heat stabilizer, a phosphate-based secondary heat stabilizer, and a lactone-based secondary heat stabilizer which may be used alone or in combination. These may be used alone or in combination of two or more.

The ultraviolet stabilizer and heat stabilizer may be used by appropriately adjusting the content at a level that does not affect the ultraviolet curability, and specifically, it is preferable that they are included in an amount of 0.1 to 3 parts by weight based on 100 parts by weight of the total hard coating composition of the present disclosure.

The additives can be added by appropriately adjusting the content within a range that does not hinder the effects of the present disclosure.

The hard coating layer may be prepared by a method known in the art. The thickness of the first hard coating layer is not particularly limited, and may be, for example, 5 to 100 μm, and the thickness of the second hard coating layer may be 3 to 15 μm, preferably 5 to 10 μm. When the thickness is within the above range, it may exhibit excellent hardness and flexibility.

The hard coating film according to an embodiment of the present disclosure may be one in which a first hard coating layer 120a may be formed by coating a first hard coating composition on a display glass 110 and performing drying and UV curing steps, and then a second hard coating layer 120b may be formed by coating a second hard coating composition on the first hard coating layer 120a and performing curing and UV curing steps in the same manner as the first hard coating layer.

The step of drying the hard coating film may be performed by a heating means such as a hot plate, a hot air circulation furnace, an infrared furnace, etc., and may be performed at a temperature of 50 to 150° C. or 50 to 100° C.

In the step of curing the hard coating film, active rays such as UV rays of 50 to 1000 mJ/cm², preferably 200 to 800 mJ/cm², are irradiated. In particular, the adhesion between the second hard coating layer and the first hard coating layer may be further strengthened by performing the step of forming the first hard coating layer 120a by performing primary curing weakly at a level of 50 to 600 mJ/cm², and performing the step of forming the second hard coating layer 120b by irradiating UV with a strong amount of light of 300 to 800 mJ/cm². Light sources used in the irradiation may include low-pressure mercury lamps, high-pressure mercury lamps, ultrahigh-pressure mercury lamps, metal halide lamps, and argon gas lasers, and in some cases, they may also include X-rays, electron beams, etc.

### <Window and Image Display Device>

Embodiments of the present disclosure provide a window and an image display device including the above-described display glass and hard coating film.

For example, the above-described hard coating film or a laminate including the same may be applied as a window or a window laminate, and at least one of a polarizing layer or a touch sensor layer may be laminated on one surface of the window on which the hard coating film is formed. Such a window or window laminate may be applied as a window film formed on the outermost surface of the image display device. In addition, the hard coating film may be inserted into the interior of the image display device, for example.

The image display device may include various image display devices such as a liquid crystal display device, an electroluminescence display device, a plasma display device, a field emission display device, and the like, and may be a flexible display device having flexibility and bending characteristics.

In this case, the hard coating laminates according to the embodiments of the present disclosure may be more effectively applied as a window or a window laminate of the flexible display device. Through the interaction of the substrate layer and the adhesive layer included in the hard coating films according to the embodiments of the present disclosure, the flexibility and durability of the window may be improved together, and antistatic performance may be implemented together. Accordingly, for example, the impact resistance and wear resistance of the flexible display device may be improved, and at the same time, damages such as cracks and peeling may be prevented even when flexing or bending.

### MODE FOR CARRYING OUT THE INVENTION

Hereinafter, embodiments of the present disclosure will be specifically described. However, the present disclosure is not limited to the embodiments disclosed below, but can be implemented in various different forms, and these embodiments are provided only to ensure that the disclosure of the present disclosure is complete and to fully inform those skilled in the art to which the present disclosure pertains of the scope of the invention, and the present disclosure is defined only by the scope of the claims. “%” and “part” are mass % and mass part, respectively, unless specifically stated.

### Preparation Example: Preparation of Hard Coating Composition

### Preparation Example 1

5 parts by weight of 14-functional acrylate (Osaka Yuki Chemical Co., Ltd., VISCOAT #1000), 43 parts by weight of 6-functional urethane acrylate (Shin-Nakamura Chemical Co., Ltd., U-6LPA), 1 part by weight of 1-hydroxycyclohexyl phenyl ketone, 1 part by weight of fluorine-based UV-curable functional group-containing compound (Shin-Etsu Co., Ltd., KY-1203), and 50 parts by weight of methyl ethyl ketone were mixed using a stirrer and filtered using a filter made of polypropylene (PP) to prepare a second hard coating composition.

### Preparation Example 2

5 parts by weight of 14-functional acrylate (Osaka Yuki Chemical Co., Ltd., VISCOAT #1000), 43 parts by weight of 6-functional urethane acrylate (Shin-Nakamura Chemical Co., Ltd., U-6LPA), 1 part by weight of 1-hydroxycyclohexyl phenyl ketone, 1 part by weight of fluorine-based UV-curable functional group-containing compound (Fluoro Technology Co., Ltd., FS-7026), and 50 parts by weight of methyl ethyl ketone were mixed using a stirrer and filtered using a filter made of polypropylene (PP) to prepare a second hard coating composition.

### Preparation Example 3

44 parts by weight of a bifunctional acrylate (Miwon Specialty Chemical Co., Ltd., UA5216), 0.5 parts by weight of 1-hydroxycyclohexyl phenyl ketone, 0.5 parts by weight of a silicone-based additive (BYK Co., Ltd., BYK-UV3530), 50 parts by weight of methyl ethyl ketone, and 5 parts by weight of an acrylic silane compound (Shin-Etsu Silicone Co., Ltd., KR-513) were mixed using a stirrer and filtered using a filter made of polypropylene (PP) to prepare a first hard coating composition.

### Preparation Example 4

40 parts by weight of a bifunctional acrylate (Miwon Specialty Chemical Co., Ltd., UA5216), 4 parts by weight of a 14-functional acrylate (Osaka Yuki Chemical Co., Ltd., VISCOAT #1000), 0.5 parts by weight of 1-hydroxycyclohexyl phenyl ketone, 0.5 parts by weight of a silicone-based additive (BYK Co., Ltd., BYK-UV3530), 50 parts by weight of methyl ethyl ketone, and 5 parts by weight of an acrylic silane compound (Shin-Etsu Silicone Co., Ltd., KBM-5803) were mixed using a stirrer and filtered using a filter made of polypropylene (PP) to prepare a first hard coating composition.

### Preparation Example 5

33 parts by weight of a bifunctional acrylate (Miwon Specialty Chemical Co., Ltd., UA5216), 11 parts by weight of a 14-functional acrylate (OsakaYuki Chemical Co., Ltd., VISCOAT #1000), 0.5 parts by weight of 1-hydroxycyclohexyl phenyl ketone, 0.5 parts by weight of a silicone-based additive (BYK Co., Ltd., BYK-UV3530), 50 parts by weight of methyl ethyl ketone, and 5 parts by weight of an acrylic silane compound (Shin-Etsu Silicone Co., Ltd., KBM-503) were mixed using a stirrer and filtered using a filter made of polypropylene (PP) to prepare a first hard coating composition.

### Preparation Example 6

22 parts by weight of a bifunctional acrylate (Miwon Specialty Chemical Co., Ltd., UA5216), 22 parts by weight of a 14-functional acrylate (OsakaYuki Chemical Co., Ltd., VISCOAT #1000), 0.5 parts by weight of 1-hydroxycyclohexyl phenyl ketone, 0.5 parts by weight of a silicone-based additive (BYK Co., Ltd., BYK-UV3530), 50 parts by weight of methyl ethyl ketone, and 5 parts by weight of an acrylic silane compound (Shin-Etsu Silicone Co., Ltd., KBM-5803) were mixed using a stirrer and filtered using a filter made of polypropylene (PP) to prepare a first hard coating composition.

### Preparation Example 7

11 parts by weight of a bifunctional acrylate (Miwon Specialty Chemical Co., Ltd., UA5216), 33 parts by weight of a 14-functional acrylate (OsakaYuki Chemical Co., Ltd., VISCOAT #1000), 0.5 parts by weight of 1-hydroxycyclohexyl phenyl ketone, 0.5 parts by weight of a silicone-based additive (BYK Co., Ltd., BYK-UV3530), 50 parts by weight of methyl ethyl ketone, and 5 parts by weight of an acrylic silane compound (Shin-Etsu Silicone Co., Ltd., KBM-503) were mixed using a stirrer and filtered using a filter made of polypropylene (PP) to prepare a first hard coating composition.

### Preparation Example 8

44 parts by weight of a 14-functional acrylate (Osaka Yuki Chemical Co., Ltd., VISCOAT #1000), 0.5 parts by weight of 1-hydroxycyclohexyl phenyl ketone, 0.5 parts by weight of a silicone-based additive (BYK Co., Ltd., BYK-UV3530), 50 parts by weight of methyl ethyl ketone, and 5 parts by weight of an acrylic silane compound (Shin-Etsu Silicone Co., Ltd., KR-513) were mixed using a stirrer and filtered using a filter made of polypropylene (PP) to prepare a first hard coating composition.

### Preparation Example 9

21.75 parts by weight of a bifunctional acrylate (Miwon Specialty Chemical Co., Ltd., UA5216), 21.75 parts by weight of a 14-functional acrylate (Osaka Yuki Chemical Co., Ltd., VISCOAT #1000), 0.5 parts by weight of 1-hydroxycyclohexyl phenyl ketone, 0.5 parts by weight of a cationic initiator (IGM Co., Ltd., Omnirad-250), 0.5 parts by weight of a silicone-based additive (BYK Co., Ltd., BYK-UV3530), 50 parts by weight of methyl ethyl ketone, and 5 parts by weight of an acrylic siloxane compound (Sooyangchemtec Co., Ltd., ASO-101) were mixed using a stirrer and filtered using a PP filter to manufacture a first hard coating composition.

### Preparation Example 10

21.75 parts by weight of a bifunctional acrylate (Miwon Specialty Chemical Co., Ltd., UA5216), 21.75 parts by weight of a 14-functional acrylate (Osaka Yuki Chemical Co., Ltd., VISCOAT #1000), 0.5 parts by weight of 1-hydroxycyclohexyl phenyl ketone, 0.5 parts by weight of a cationic initiator (IGM Co., Ltd., Omnirad-250), 0.5 parts by weight of a silicone-based additive (BYK Co., Ltd., BYK-UV3530), 50 parts by weight of methyl ethyl ketone, and 5 parts by weight of an epoxy-based silane compound (Shin-Etsu Silicone Co., Ltd., KR-517) were mixed using a stirrer and filtered using a filter made of polypropylene (PP) to prepare a first hard coating composition.

### Preparation Example 11

5 parts by weight of a 14-functional acrylate (Osaka Yuki Chemical Co., Ltd., VISCOAT #1000), 43 parts by weight of a 6-functional urethane acrylate (Shin-Nakamura Chemical Co., Ltd., U-6LPA), 1 part by weight of 1-hydroxycyclohexyl phenyl ketone, 1 part by weight of a silicone-based additive (BYK Co., Ltd., BYK-307), and 50 parts by weight of methyl ethyl ketone were mixed using a stirrer and filtered using a filter made of polypropylene (PP) to prepare a second hard coating composition.

### Preparation Example 12

24.5 parts by weight of a bifunctional acrylate (Miwon Specialty Chemical Co., Ltd., UA5216), 24.5 parts by weight of a 14-functional acrylate (Osaka Yuki Chemical Co., Ltd., VISCOAT #1000), 0.5 parts by weight of 1-hydroxycyclohexyl phenyl ketone, 0.5 parts by weight of a silicone-based additive (BYK Co., Ltd., BYK-UV3530), and 50 parts by weight of methyl ethyl ketone were mixed using a stirrer and filtered using a filter made of polypropylene (PP) to prepare a first hard coating composition.

### Examples and Comparative Examples: Manufacturing of Hard Coating Films

The hard coating compositions of Preparation Examples 1 to 12 were laminated in the order described in Table 1 and Table 2 below to manufacture hard coating films.

Specifically, in order to form a first hard coating layer on a 50 μm thin glass, the composition of each Preparation Example was coated using a No. 40 bar coater, and then the solvent was dried at 90° C. for 2 minutes. The dried coating film was irradiated with UV at a light dose of 600 mJ/cm² to form a first hard coating layer (HC1) of 25 μm. The composition of the Preparation Example suitable for each Example was coated on the formed first hard coating layer to form a second hard coating layer (HC2). The composition of each Example was coated as the second hard coating composition using a No. 12 bar coater, and then the solvent was dried at 90° C. for 2 minutes. The dried coating film was purged with nitrogen, and UV was irradiated with a light dose of 600 mJ/cm² under nitrogen conditions to form a 7 μm second hard coating layer, thereby manufacturing a final laminated hard coating film.

In the case of Comparative Example 6, the second hard coating composition was coated with a No. 3 bar coater using the composition of the Preparation Example 1 of the second hard coating layer was coated, and then the solvent was dried at 90° C. for 2 minutes. The dried coating film was purged with nitrogen, and UV was irradiated with a light dose of 600 mJ/cm² under nitrogen conditions to form a 1 μm second hard coating layer, thereby manufacturing a final laminated hard coating film.

In the case of Comparative Example 7, the second hard coating composition was coated with a No. 25 bar coater using the composition of the Preparation Example 1 of the second hard coating layer was coated, and then the solvent was dried at 90° C. for 2 minutes. The dried coating film was purged with nitrogen, and UV was irradiated with a light dose of 600 mJ/cm² under nitrogen conditions to form a 20 μm second hard coating layer, thereby manufacturing a final laminated hard coating film.

TABLE 1

| | | Example 1 | Example 2 | Example 3 | Example 4 | Example 5 | Example 6 | Example 7 | Example 8 | Example 9 |
|---|---|---|---|---|---|---|---|---|---|---|
| Structure | HC2 | Preparation | Preparation | Preparation | Preparation | Preparation | Preparation | Preparation | Preparation | Preparation |
| | | Example 1 | Example 1 | Example 1 | Example 1 | Example 1 | Example 2 | Example 2 | Example 2 | Example 2 |
| | HC1 | Preparation | Preparation | Preparation | Preparation | Preparation | Preparation | Preparation | Preparation | Preparation |
| | | Example 3 | Example 4 | Example 5 | Example 6 | Example 7 | Example 5 | Example 7 | Example 9 | Example 10 |
| | | Glass | Glass | Glass | Glass | Glass | Glass | Glass | Glass | Glass |

| | | | | | | | | | |
|---|---|---|---|---|---|---|---|---|---|
| HC2 thickness | 7 | 7 | 7 | 7 | 7 | 7 | 7 | 7 | 7 |
| (μm) | | | | | | | | | |
| Permeability | 91.9 | 91.8 | 91.9 | 92 | 91.9 | 92.1 | 91.9 | 92.1 | 91.9 |
| Scratch resistance | ◯ | ◯ | ◯ | ◯ | ◯ | ◯ | ◯ | ◯ | ◯ |
| Pencil hardness | 3H | 3H | 3H | 3H | 3H | 3H | 3H | 3H | 3H |
| Antifouling | 111 | 110 | 112 | 111 | 110 | 110 | 111 | 110 | 111 |
| properties | | | | | | | | | |
| Wear resistance | 105 | 103 | 98 | 103 | 103 | 100 | 99 | 100 | 99 |
| Chemical | 105 | 100 | 97 | 99 | 99 | 98 | 99 | 98 | 99 |
| resistance | | | | | | | | | |
| Pressing | ◯ | ◯ | ◯ | ◯ | ◯ | ◯ | ◯ | ◯ | ◯ |
| resistance | | | | | | | | | |
| Anti-flying | ◯ | ◯ | ◯ | ◯ | ◯ | ◯ | ◯ | ◯ | ◯ |
| properties | | | | | | | | | |
| Adhesion | ◯ | ◯ | ◯ | ◯ | ◯ | ◯ | ◯ | ◯ | ◯ |
| Flexural | ◯ | ◯ | ◯ | ◯ | ◯ | ◯ | ◯ | ◯ | ◯ |
| properties | | | | | | | | | |
| HC1 Vickers | 1.1 | 3.1 | 6.3 | 12.4 | 16.8 | 6.3 | 16.8 | 13.2 | 12.1 |
| hardness | | | | | | | | | |
| [kgf/mm²] | | | | | | | | | |

TABLE 2

| | | Comparative | Comparative | Comparative | Comparative | Comparative | Comparative | Comparative |
|---|---|---|---|---|---|---|---|---|
| | | Example 1 | Example 2 | Example 3 | Example 4 | Example 5 | Example 6 | Example 7 |
| Structure | HC2 | Preparation | Preparation | Preparation | Preparation | — | Preparation | Preparation |
| | | Example 2 | Example 11 | Example 1 | Example 1 | | Example 1 | Example 1 |
| | HC1 | Preparation | Preparation | Preparation | — | Preparation | Preparation | Preparation |
| | | Example 8 | Example 6 | Example 12 | | Example 6 | Example 4 | Example 4 |
| | | Glass | Glass | Glass | Glass | Glass | Glass | Glass |

| | | | | | | | |
|---|---|---|---|---|---|---|---|
| HC2 thickness (μm) | 7 | 7 | 7 | 7 | 7 | 1 | 20 |
| Permeability | 91.9 | 91.9 | 92 | 91.8 | 91.9 | 91.7 | 91.5 |
| Scratch resistance | ◯ | X | ◯ | ◯ | X | ◯ | ◯ |
| Pencil hardness | 3H | 3H | 3H | 3H | H | 3H | 3H |
| Antifouling properties | 111 | 97 | 80 | 110 | 73 | 110 | 110 |
| Wear resistance | 97 | 82 | 56 | 98 | 56 | 84 | 98 |
| Chemical resistance | 97 | 76 | 58 | 96 | 52 | 78 | 97 |
| Pressing resistance | X | ◯ | ◯ | X | ◯ | ◯ | ◯ |
| Anti-flying properties | X | X | ◯ | X | ◯ | ◯ | ◯ |
| Adhesion | ◯ | ◯ | X | X | ◯ | ◯ | ◯ |
| Flexural properties | ◯ | ◯ | X | ◯ | ◯ | ◯ | X |
| HC1 Vickers hardness | 21.1 | 12.4 | 12.6 | — | 12.4 | 3.1 | 3.1 |
| [kgf/mm²] | | | | | | | |

### Experimental Example

The physical properties of the hard coating films manufactured in the above Examples 1 to 9 and Comparative Examples 1 to 7 were measured by the following methods, and the results are shown in Table 1 and Table 2.

### (1) Permeability Evaluation

The permeabilities of the coating films were measured using Murakami Corporation's Haze meter HM-150N.

### (2) Scratch Resistance Evaluation

The substrate film was bonded to glass using a transparent pressure-sensitive adhesive so that the hard coating side faced upward, and then the scratch resistance was measured by reciprocally rubbing it 10 times with a load of 500 g/cm² using steel wool (#0000).

### <Evaluation Criteria>

◯: When the measurement section is observed by transmitting and reflecting it with a three-wavelength lamp, no scratches are visible or 10 or fewer scratches are visible.
X: When the measurement section is observed by transmitting and reflecting it with a three-wavelength lamp, more than 10 scratches are visible.

### (3) Pencil Hardness Evaluation

After fixing the substrate film to glass so that the hard coating surface faced upward, the pencil hardness was measured under a load of 1 kg. The test was performed 5 times to a 1 cm length using a pencil with the same hardness, and the hardness that was OK 4 times or more was indicated as the pencil hardness.

### (4) Antifouling Property Evaluation

The contact angle of water was measured using a contact angle measuring device DSA100 of KRUSS. The amount of liquid droplet at room temperature was 3 μl. The case where the contact angle of water of 110° or higher was selected as the contact angle pass criterion.

### (5) Wear Resistance Evaluation

The measurement was performed using Daesung Precision's wear resistance measuring equipment. The coating surface was rubbed 3,000 times using an eraser and a 500 g weight for wear resistance testing, and then the contact angle was measured. At this time, the case where the contact angle of water was 95° or higher was selected as the wear resistance pass criterion.

### (6) Chemical Resistance Evaluation

The measurement was performed using Daesung Precision's wear resistance measuring equipment. The coating surface was rubbed 3,000 times using an eraser and a 500 g weight for wear resistance testing, and then the contact angle was measured. Ethanol (purity 99.8%) was applied to the rubbed sample every 50 times. At this time, the case where the contact angle of water was 95° or higher was selected as the wear resistance pass criterion.

### (7) POGO Pressing Resistance Evaluation

After fixing the manufactured hard-coated glass with a pressure-sensitive adhesive (25 μm), the surface compression performance was evaluated using POGO compression equipment.

After pressing the hard-coated surface to 4 kg using a 5 mm POGO tip, the film was left under 25° C. and 50% environmental conditions, and after 24 hours, whether the pressed portion was visible or not was checked.

### <Evaluation Criteria>

◯: 4 kg not visible
X: 4 kg visible

### (8) Anti-Flying Evaluation

The opposite surface of the manufactured hard-coated glass was bent in a state that a pressure-sensitive adhesive (25 μm) was bonded thereto, and compression was applied thereto to press it using Universal Testing Machine (UTM) equipment until it broke.

The condition of the hard-coated surface of the broken sample was checked to check if any broken glass fragments had fallen out or separated to the outside of the back of the hard-coated surface.

### <Evaluation Criteria>

◯: No glass fragments checked
X: Glass fragments checked

### (9) Adhesion Evaluation

After bonding the substrate film to glass so that the hard coating surface faced upward using a transparent pressure-sensitive adhesive, the hard coating surface was scratched with a cutter knife in the shape of 100 squares at 1 mm intervals, and an adhesion test was performed three times using a Nichiban tape.

The results were expressed as “the number of squares that were OK after the adhesion test/100”.

### <Evaluation Criteria>

◯: 100/100
X: 0˜99/100

### (10) Vickers Hardness Measurement

The sample was placed so that the first hard coating layer faced upward, and the Vickers hardness of the first hard coating layer for compression measured to a micro load of 5 mN was measured using a nanoindenter (Fischer).

### (11) Flexural Property Evaluation

The manufactured hard coating film was subjected to a folding test 200,000 times so that the second hard coating layers were in contact with each other and the radius of curvature of the folded portion was set to 5 mm.

### <Evaluation Criteria>

◯: No cracks or breakage
X: No cracks or breakage

Referring to the experimental data in Tables 1 and 2 above, in the cases of Examples 1 to 9 in which the laminate according to the embodiment of the present disclosure was applied, pencil hardnesses thereof were 3H or higher, and excellent results were shown in all of the evaluations of scratch resistance, antifouling properties, wear resistance, chemical resistance, pressing resistance, anti-flying properties, adhesion, and flexural properties, whereas in Comparative Examples 1 to 7 in which the hard coating layer deviated from the embodiments of the present disclosure, one or more evaluation criteria among the evaluations of scratch resistance, antifouling properties, wear resistance, chemical resistance, pressing resistance, anti-flying properties, adhesion, and flexural properties did not reach the present disclosure, and thus did not exhibit physical properties suitable for use as a hard coating film for flexible displays. In particular, in the case of Comparative Example 1 in which the Vickers hardness of the first hard coating layer exceeded 20 kgf/mm², a compression phenomenon was observed in the evaluation of pressing resistance, and glass fragments were confirmed in the evaluation of anti-flying properties. In addition, in the case of Comparative Example 6 in which the thickness of the second hard coating layer is less than 3 μm, the contact angle of water was measured to be less than 950 in the wear resistance and chemical resistance evaluation, and in the case of Comparative Example 7 in which the thickness of the second hard coating layer exceeds 15 μm, cracks or breakage occurred in the flexural property evaluation.

Therefore, it can be confirmed that the hard coating film according to the present disclosure and the window and image display device applying the same have excellent physical properties in terms of durability during repeated folding, and in particular, have a flying prevention effect when broken.

### INDUSTRIAL APPLICABILITY

The hard coating film according to the present disclosure and the window and image display device applying the same have a pencil hardness of 3H or higher and are excellent in scratch resistance, antifouling resistance, wear resistance, chemical resistance, pressing resistance, anti-flying properties, adhesion, and flexural properties, so that when applied to the flexible displays, the device reliability may be improved.

1. A hard coating film comprising:
a first hard coating layer which is formed on a display glass, contains a silane or siloxane compound, and has a Vickers hardness of 20 kgf/mm² or less; and
a second hard coating layer which is formed on the first hard coating layer, contains a fluorine-based UV curable functional group-containing compound, and has a thickness of 3 to 15 μm.

2. The hard coating film of claim 1, wherein the display glass is an ultrathin glass (UTG).

3. The hard coating film of claim 1, wherein the display glass, the first hard coating layer, and the second hard coating layer are formed by directly contacting each other without including a separate layer.

4. The hard coating film of claim 1, wherein the fluorine-based UV curable functional group-containing compound has 1 to 6 UV-curable functional groups.

5. The hard coating film of claim 1, wherein any one hard coating layer of the first hard coating layer and the second hard coating layer is prepared from a composition comprising one or more selected from the group consisting of a photopolymerizable compound, an initiator, and a solvent.

6. The hard coating film of claim 5, wherein the photopolymerizable compound further includes an inorganic nano filler.

7. The hard coating film of claim 1, wherein any one hard coating layer of the first hard coating layer and the second hard coating layer further contains an additive.

8. The hard coating film of claim 7, wherein the additive includes one or more selected from the group consisting of a leveling agent, an ultraviolet stabilizer, and a heat stabilizer.

9. The hard coating film of claim 1, which is applied to a flexible display.

10. A window comprising:
a display glass; and
a hard coating film formed on the display glass,
wherein the hard coating film includes the hard coating film according to claim 1.

11. An image display device comprising the window according to claim 10.
